(19) United States
(12) Patent Application Publication
(10) Pub. No.: US 2026/0238148 A1
(43) Pub. Date: Aug. 13, 2026

(54) Method for Identifying the Spatial Harmonic Flux-Map of a Synchronous Electrical Machine, and Method for Torque Ripple Map Evaluation Without Torque Measurement

(71) Applicant: Politecnico Di Torino, Torino (IT)

(72) Inventors: Anantaram Varatharajan, Mountain View, CA (US); Gianmario Pellegrino, Torino (IT); Simone Ferrari, Torino (IT); Paolo Pescetto, Torino (IT)

(21) Appl. No.: 19/154,268

(22) PCT Filed: Feb. 2, 2024
(86) PCT No.: PCT/IB2024/050965

§ 371 Date: Aug. 6, 2025

(30) Foreign Application Priority Data
Feb. 7, 2023 (IT) 102023000002001

(51) Int. Cl. H02P 21/14; G01R 31/34; H02P 21/20; H02P 21/22

(52) U.S. Cl. CPC H02P 21/141; H02P 21/20; H02P 21/22; G01R 31/343; H02P 2207/05

(57) ABSTRACT

A method for identifying the spatial harmonic flux-map of an electrical machine includes: driving the electrical machine at a constant speed by way of an external driver; scanning a dq current plane of the electrical machine by way of a proportional-integral current controller; acquiring phase current, line voltage and rotor position of the electrical machine during the scanning; calculating the stator flux-linkage in a stationary reference frame from a voltage equation from at least one electrical cycle data extracting harmonics in the measured phase current by way of a Fourier transform; extracting harmonics in the estimated stator flux in a synchronous reference frame by way of a Fourier transform; wherein the expressions Λ_{d}=I_{d}L_{d}+λₘ; Λ_{q}=I_{q}L_{q} hold wherein Λ_{d}; Λ_{q}; λₘ are columns vector flux matrix, I_{d}; I_{q} are a square matrix, L_{d}; L_{q} are inductance column vector matrix.

### TECHNICAL FIELD

The present invention generally relates to a method for identifying the spatial harmonic flux-map of a synchronous electrical machine. Secondly, the present invention also relates to a method for identifying the torque-map of said synchronous electrical machine, including the torque ripple due to spatial harmonics. For example, said electrical machine is a permanent magnets synchronous machine or a synchronous reluctance machine.

### BACKGROUND ART

Accurate modelling of electrical machines finds increasing importance in the design and development of high-performance motor drives. Most synchronous machines exhibit non-linear magnetic characteristics with saturation and cross-saturation phenomena; this flux-to-current relationship is referred to as flux-map.

As known, an accurate flux-map is imperative for model-based control techniques and in evaluating the optimal control trajectories such as maximum-torque-per-ampere (MTPA) and maximum-torque-per-volt (MTPV) and becomes even more critical in case of encoderless control.

An experimental identification procedure for identifying the flux map using proportional-integral-resonant (PIR) current controllers is described in J. Lee, Y.-C. Kwon, and S.-K. S. AE, “Identification of IPMSM Flux-Linkage Map for High-Accuracy Simulation of IPMSM Drives,” IEEE Trans. Power Electron., p. 1, 2021, doi: 10.1109/TPEL.2021.3084558, wherein a discrete Fourier transform (DFT) is used to extract the harmonics. Each harmonic order is taken care of by a dedicated PIR controller to ensure a constant current regulation such that the harmonics are reflected in the back-emf. However, this requires prior knowledge of the dominant harmonics which is not readily available for commercial off-the-shelf motors. Moreover, the dominant flux-linkage harmonic is of the same order of the number of stator slots per pole pair. The feasibility of PIR controller for machines with higher dominant harmonic order (e.g. 18th, 24th, etc.) is challenging and depends on factors such as operating speed and sampling frequency.

As known, the spatial flux harmonics along with the variation in the internal magnetic energy manifest as torque ripples in the machine. The identification of torque ripple finds importance in motor design validation, high fidelity control simulation and accurate torque control development. In particular, the torque ripple experimental measurement is a nontrivial task requiring a dedicated and carefully assembled test-bench.

As described in “Torque Ripple Minimization of PM-assisted Synchronous Reluctance Machines via Asymmetric Rotor Poles,” 2019, IEEE, Energy Conversion Congress and Exposition 2019, (ECCE), pp. 4895-4902, doi: 10.1109/ECCE.2019.8912470, a worm screw reducer can be placed between a driving machine and a torque meter to establish a ripple-less load shaft and impose a low constant speed.

A position-controlled driving machine for torque measurement at zero speed is also described in H.-J. Cho, Y.-C. Kwon, and S.-K. Sul, “Torque Ripple-Minimizing Control of IPMSM with Optimized Current Trajectory,” IEEE Trans. Ind. Appl., p. 1, 2021, doi: 10.1109/TIA.2021.3075424.

A torque sensorless identification of IPMSM torque-map is also descried in H.-J. Cho, J. Lee, Y.-C. Kwon, and S.-K. Sul, “Torque-Sensorless Identification of IPMSM Torque Map,” in 2021 IEEE Energy Conversion Congress and Exposition (ECCE), 2021, pp. 4661-4667, doi: 10.1109/ECCE47101.2021.9595888, wherein a variation in the magnetic energy is expressed in terms of torque gradient using the flux-maps.

### SUMMARY OF THE INVENTION

The Applicant has perceived the need to provide a commissioning technique allowing to identify spatial harmonics in the flux-linkage of permanent magnets synchronous machines (PMSM) or synchronous reluctance machines (SyRM).

The present invention provides a method allowing to extract the spatial harmonics information from a simple experimental method of flux-linkage identification.

Moreover, advantageously, the method according to the invention also allows to evaluate the instantaneous torque harmonics from the same flux-linkage test, which is otherwise very challenging to measure and requires a dedicated and specialized test-bench and a torque transducer.

According to a first aspect, the invention refers to a method for identifying the spatial harmonic flux-map of an electrical machine.

Preferably, the method comprises driving said electrical machine at a constant speed by means of an external driver.

Preferably, the method comprises scanning a dq current plane of said electrical machine by means of a proportional-integral current controller.

Preferably, the method comprises acquiring phase current, line voltage and rotor position of said electrical machine during said scanning.

Preferably, the method comprises calculating a stator flux-linkage, in a stationary reference frame αβ, from a voltage equation from at least one mechanical cycle data as

$${λ}_{α β} = \int ( {v}_{α β} - {R}_{s} {i}_{α β} ) dt$$

wherein
λ_{αβ} is the stator flux-linkage vector in a stationary reference frame;
v_{αβ} is the stator voltage vector in a stationary reference frame;
Rₛ is the stator resistance and
i_{αβ} is the stator current vector in a stationary reference frame;

Preferably, the method comprises extracting harmonics in the measured phase current by means of a Fourier transform.

Preferably, the method comprises extracting harmonics in the estimated stator flux in a synchronous reference frame by means of a Fourier transform.

Preferably, the expressions Λ_{d}=I_{d}L_{d}; Λ_{q}=I_{q}L_{q} hold wherein
Λ_{d}; Λ_{q} are columns vector flux matrix,
I_{d}; I_{q} are a square matrix,
L_{d}; L_{q} are an inductance column vector matrix.

Preferably, said electrical machine is either a permanent magnets synchronous machine or a synchronous reluctance machine.

Preferably, said constant speed is comprised between 0.2 and 0.5 p.u., preferably equal to 0.33 p.u.

Preferably, said scanning a dq current plane of said electrical machine with a proportional-integral current controller comprises setting a q-axis current (i_{q}), from a minimum value to a maxim value, at predetermined values; each value being maintained for a respective time interval (t(i)).

Preferably, said scanning a dq current plane of said electrical machine with a proportional-integral current controller comprises increasing a d-axis current (i_{d}) from a minimum value to a maximum value in each of said time intervals (t(i)).

Preferably, said harmonics in the measured phase current

$${i}_{d}^{*} , {i}_{q}^{*}$$

are expressed as:

$${i}_{d} ( {i}_{d}^{*} , {i}_{q}^{*} , θ ) = {i}_{d 0} ( {i}_{d}^{*} , {i}_{q}^{*} ) + {\sum }_{h = 6 n} {i}_{dh} ( {i}_{d}^{*} , {i}_{q}^{*} ) cos ( h θ - {ϕ}_{dh}^{i} ) \\ {i}_{q} ( {i}_{d}^{*} , {i}_{q}^{*} , θ ) = {i}_{q 0} ( {i}_{d}^{*} , {i}_{q}^{*} ) + {\sum }_{h = 6 n} {i}_{qh} ( {i}_{d}^{*} , {i}_{q}^{*} ) cos ( h θ - {ϕ}_{qh}^{i} )$$

wherein

$${i}_{d 0} = {i}_{d}^{*} and {i}_{q 0} = {i}_{q}^{*}$$

are the average currents, i_{dh} and i_{qh} are the harmonic components magnitude and

$${ϕ}_{dh}^{i} and {ϕ}_{qh}^{i}$$

are the harmonic components phase angle.

Preferably, said harmonics in the estimated stator flux

$${λ}_{d}^{*} , {λ}_{q}^{*}$$

in a synchronous reference frame are expressed as:

$${λ}_{d} ( {i}_{d}^{*} , {i}_{q}^{*} , θ ) = {λ}_{d 0} ( {i}_{d}^{*} , {i}_{q}^{*} ) + {\sum }_{h = 6 n} {λ}_{dh} ( {i}_{d}^{*} , {i}_{q}^{*} ) cos ( h θ - {ϕ}_{dh}^{λ} ) \\ {λ}_{q} ( {i}_{d}^{*} {i}_{q}^{*} , θ ) = {λ}_{q 0} ( {i}_{d}^{*} {i}_{q}^{*} ) + {\sum }_{h = 6 n} {λ}_{qh} ( {i}_{d}^{*} , {i}_{q}^{*} ) cos ( h θ - {ϕ}_{qh}^{λ} )$$

wherein λ_{d0} and λ_{q0} are the average fluxes; λ_{dh} and λ_{qh} are the harmonic components magnitude;

$${ϕ}_{dh}^{λ} and {ϕ}_{qh}^{λ}$$

are the harmonic components phase angle.

According to a second aspect, the invention refers to a method for torque ripple map evaluation, comprising:
a. Performing the above for identifying the spatial harmonic flux-map of an electrical machine;
b. Performing a torque ripple map evaluation based on the spatial harmonic flux-map of said electrical machine.

Preferably, said torque ripple map evaluation comprises:
calculating an instantaneous electromagnetic torque as

$$T ( {i}_{d} , {i}_{q} , θ ) = \frac{3 p}{2} ( {i}_{dq}^{T} J {λ}_{dq} + \frac{\partial {W}^{′}}{\partial θ} )$$

wherein
i_{dq} is the stator current vector in a synchronous reference frame;
p is the number of pole pairs of the machine;
λ_{dq} is stator flux-linkage vector in a synchronous reference frame;
W′ is the magnetic coenergy in the machine;
and the d-axis and q-axis components of the derivative of the gross co-energy

$$\frac{\partial {W}^{′}}{\partial θ}$$

are:

$$\frac{\partial {W}_{d}^{′}}{\partial θ} = - {\sum }_{h = 6 n} h {\int }_{0}^{{i}_{d}} {L}_{dh} ( τ , 0 ) sin ( h θ - {ϕ}_{dh} ) τ d τ \\ \frac{\partial {W}_{q}^{′}}{\partial θ} = - {\sum }_{h = 6 n} h {\int }_{0}^{{i}_{q}} {L}_{qh} ( {i}_{d} , τ ) sin ( h θ - {ϕ}_{qh} ) τ d τ$$

L_{d0} and L_{q0} are the fundamental inductances, L_{dh} and L_{qh} are the harmonic components magnitude; φ_{dh} and φ_{qh} are the harmonic components phase angle.

Preferably, torque measurement is not performed.

According to a third aspect, the invention refers to an identification unit.

Preferably, the identification unit is configured to perform said method for identifying the spatial harmonic flux-map of an electrical machine.

Preferably, the identification unit is configured to perform said method for torque ripple map evaluation.

### BRIEF DESCRIPTION OF THE DRAWINGS

The present invention will become clearer from the following detailed description, given by way of example and not of limitation, to be read with reference to the accompanying drawings, wherein:

FIGS. 1a-1b show block diagrams illustrating embodiments of an identification unit according to the present invention;

FIG. 2 shows exemplary current trajectories used for identifying a flux-map according to the present invention;

FIGS. 3 and 4 show a comparison of a torque harmonic amplitude and waveform at steady-state conditions evaluated from a flux map obtained according to the present invention and a reference one calculated through Finite Element Analysis (FEA).

### DETAILED DESCRIPTION OF PREFERRED EMBODIMENTS OF THE INVENTION

In the following, vectors in a rotating reference frame, associated with the rotor, are denoted by subscript dq. Vectors in a stationary reference frame, associated with the stator, are denoted by subscript αβ. Finally, abc subscript indicates machine phase quantities.

In the following, the electrical rotor position is indicated as θ and the electrical angular speed is defined as ω=dθ/dt. The orthogonal rotational matrix is J=

$$[ \begin{matrix}0 & - 1 \\ 1 & 0\end{matrix} ]$$

and I is the identity matrix.

In the following, real space vectors are used, for example, the stator current is i_{qq}=[i_{d}, i_{q}]^{T} where i_{d} and i_{q} are the vector components in the rotor reference frame. Vector notation will be adopted also for describing phase quantities, for example, i_{abc}=[iₐ, i_{b}, i_{c}]_{T}.

The voltage equation of a synchronous machine in a dq rotor reference frame can be expressed as:

$$\frac{d {λ}_{dq}}{dt} = {v}_{dq} - {R}_{s} {i}_{dq} - ω J {λ}_{dq} ( {i}_{d} , {i}_{q} , θ ) \qquad [ 1 ]$$

where Rₛ is the stator resistance, v_{dq} is the stator voltage vector and λ_{dq} is the stator flux linkage vector as a function of stator currents i_{d}, i_{q} and rotor position θ.

The time-derivative of the stator flux λ_{dq} can be expressed as

$$\frac{d {λ}_{dq}}{d t} ( {i}_{d} , {i}_{q} , θ ) = {L}_{\partial } \frac{d {i}_{dq}}{d t} + \frac{\partial {λ}_{dq}}{\partial θ} \frac{d θ}{d t} \qquad [ 2 ]$$

wherein L_{∂} is an incremental inductance matrix given by

$${L}_{\partial } ( {i}_{d} , {i}_{q} , θ ) = \frac{\partial {λ}_{dq}}{\partial {i}_{dq}} = [ \begin{matrix}{l}_{d} & {l}_{dp} \\ {l}_{dq} & {l}_{q}\end{matrix} ] \qquad [ 3 ]$$

wherein the diagonal terms l_{d} and l_{q} represent the incremental inductance along the direct axis d and the quadrature axis q; while the term l_{dq} is the cross-saturation term which can be expressed as:

$${l}_{dq} = \frac{d {λ}_{d}}{d {i}_{q}} ( {i}_{d} , {i}_{q} , θ ) = \frac{d {λ}_{q}}{d {i}_{d}} ( {i}_{d} , {i}_{q} , θ ) \qquad [ 4 ]$$

In the following, unless mentioned otherwise, all electrical quantities are functions of the stator currents i_{d}, i_{q} and of the rotor position θ.

In the absence of eccentricity and mechanical defects, spatial harmonics exist as multiples of 6n in the synchronous dq reference frame. In particular, the stator flux-linkage λ_{dq} with spatial harmonics can be expressed as

$${λ}_{dq} ( {i}_{d} , {i}_{q} , θ ) = L {i}_{dq} + {λ}_{m} ( {i}_{q} , θ ) ; wherein L ( {i}_{d} , {i}_{q} , θ ) = [ \begin{matrix}{L}_{d} & 0 \\ 0 & {L}_{q}\end{matrix} ] ; {λ}_{m} ( {i}_{q} , θ ) = [ \begin{matrix}{λ}_{d} ( 0 , {i}_{q} , θ ) \\ 0\end{matrix} ] \qquad [ 5 ]$$

wherein L_{d} and L_{q} are the apparent inductances along d and q-axes, respectively; λₘ is the PM flux linkage vector, aligned with the d axis. The cross-saturation effect is included into the L_{d}, L_{q} and λₘ terms, and λₘ=0 for the Synchronous Reluctance (SyR) machine.

The spatial harmonic inductances may be modelled as

$${L}_{d} ( {i}_{d} , {i}_{q} , θ ) = {L}_{d 0} ( {i}_{d} , {i}_{q} ) + {\sum }_{h = 6 n} {L}_{dh} ( {i}_{d} , {i}_{q} ) cos ( h θ - {ϕ}_{dh} ) \qquad [ 6 a ]$$

$${L}_{q} ( {i}_{d} , {i}_{q} , θ ) = {L}_{q 0} ( {i}_{d} , {i}_{q} ) + {\sum }_{h = 6 n} {L}_{q h} ( {i}_{d} , {i}_{q} ) cos ( h θ - {ϕ}_{qh} ) \qquad [ 6 b ]$$

wherein n is a positive integer, L_{d0} and L_{q0} are the fundamental inductances, L_{dh}(i_{d}, i_{q}) and L_{qh}(i_{d}, i_{q}) are the harmonic components magnitude of the inductances; φ_{dh} and φ_{qh} are the harmonic components phase angle of the inductances.

The stator flux-linkage λ_{αβ} is estimated in the stationary reference frame αβ from the voltage equation from one mechanical cycle data as

$${λ}_{α β} = \int ( {v}_{α β} - {R}_{s} {i}_{α β} ) dt \qquad [ 7 ]$$

For a reference current vector condition

$${i}_{dq}^{*} ,$$

the harmonics in the measured current, extracted using Fourier transform can be expressed as

$${i}_{d} ( {i}_{d}^{*} , {i}_{q}^{*} , θ ) = {i}_{d 0} ( {i}_{d}^{*} , {i}_{q}^{*} ) + {\sum }_{h = 6 n} {i}_{dh} ( {i}_{d}^{*} , {i}_{q}^{*} ) cos ( h θ - {ϕ}_{dh}^{i} ) \qquad [ 8 a ]$$

$${i}_{q} ( {i}_{d}^{*} , {i}_{q}^{*} , θ ) = {i}_{q 0} ( {i}_{d}^{*} , {i}_{q}^{*} ) + {\sum }_{h = 6 n} {i}_{qh} ( {i}_{d}^{*} , {i}_{q}^{*} ) cos ( h θ - {ϕ}_{qh}^{i} ) \qquad [ 8 b ]$$

wherein

$${i}_{d 0} = {i}_{d}^{*} and {i}_{q 0} = {i}_{q}^{*}$$

are the average currents, i_{dh} and i_{qh} are the harmonic current components magnitude and

$${ϕ}_{dh}^{i} and {ϕ}_{qh}^{i}$$

are the harmonic current components phase angle.

Similarly, the harmonics in the estimated stator flux in the synchronous reference frame from the Fourier transform can be expressed as:

$${λ}_{d} ( {i}_{d}^{*} , {i}_{q}^{*} , θ ) = {λ}_{d 0} ( {i}_{d}^{*} , {i}_{q}^{*} ) + {\sum }_{h = 6 n} {λ}_{dh} ( {i}_{d}^{*} , {i}_{q}^{*} ) cos ( h θ - {ϕ}_{dh}^{λ} ) \qquad [ 9 a ]$$

$${λ}_{q} ( {i}_{d}^{*} , {i}_{q}^{*} , θ ) = {λ}_{q 0} ( {i}_{d}^{*} , {i}_{q}^{*} ) + {\sum }_{h = 6 n} {λ}_{q h} ( {i}_{d}^{*} , {i}_{q}^{*} ) cos ( h θ - {ϕ}_{q h}^{λ} ) \qquad [ 9 b ]$$

wherein λ_{d0} and λ_{q0} are the average flux linkage components; Λ_{dh} and λ_{qh} are the harmonic flux components magnitude;

$${ϕ}_{dh}^{λ} and {ϕ}_{q h}^{λ}$$

are the harmonic flux components phase angle.

The sine and cosine components of the d-axis harmonic flux can be represented as the resulting interaction between the harmonic currents and the harmonic inductance. In particular, the sine and cosine components of the d-axis harmonic flux in equation [9a],

$${λ}_{dh} ( {i}_{d}^{*} , {i}_{q}^{*} ) cos ( {ϕ}_{dh}^{λ} ) and {λ}_{dh} ( {i}_{d}^{*} , {i}_{q}^{*} ) sin ( {ϕ}_{dh}^{λ} ) ,$$

can be represented as the resulting interaction between the harmonic currents in [8],

$${i}_{dh} ( {i}_{d}^{*} , {i}_{q}^{*} ) cos ( {ϕ}_{dh}^{i} ) and {i}_{dh} ( {i}_{d}^{*} , {i}_{q}^{*} ) sin ( {ϕ}_{dh}^{i} ) ,$$

and the harmonic inductances in [6], L_{dh}(i_{d}, i_{q}) cos(φ_{dh}) and L_{dh}(i_{d}, i_{q}) sin(φ_{dh}). This is encapsulated in the expression

$${Λ}_{d} = {I}_{d} {L}_{d} + {λ}_{𝔪} \to {L}_{d} = {I}_{d}^{- 1} ( {Λ}_{d} - {λ}_{𝔪} ) \qquad [ 10 ]$$

wherein Λ_{d} is a columns vector flux matrix, I_{d} is a square matrix, L_{d} is an inductance column vector matrix. As example, the expression for the 6^{th} and the 12^{th} harmonics of the aforementioned three matrices are given in expression [11a, 11b, 11c]:

$${I}_{d} = \frac{1}{2} [ \text{?} ] \qquad [ 11 a ]$$

$${L}_{d} = [ {L}_{d 0} {L}_{d 6} cos ( {ϕ}_{d 6} ) {L}_{d 6} sin ( {ϕ}_{d 6} ) {L}_{d 12} cos ( {ϕ}_{d 12} ) {L}_{d 12} sin ( {ϕ}_{d 12} ) ] \qquad [ 11 b ]$$

$${Λ}_{d} = [ {λ}_{d 0} {λ}_{d 6} cos ( {ϕ}_{d 6}^{λ} ) {λ}_{d 6} sin ( {ϕ}_{d 6}^{λ} ) {λ}_{d 12} cos ( {ϕ}_{d 12}^{λ} ) {λ}_{d 12} sin ( {ϕ}_{d 12}^{λ} ) ] \qquad [ 11 c ]$$

$$\text{?} \text{indicates text missing or illegible when filed}$$

For the sake of brevity, only the 6^{th} and 12^{th} harmonics are considered but the above equation can be easily extended for higher orders.

Similar equations (10)-(11) also apply for the q-axis.

Moreover, according to a second aspect of the present invention, an analytical expression for the instantaneous torque using the law of energy conservation, and considering saturation, cross-saturation and spatial harmonics can be calculated.

In particular, the input electrical energy of a synchronous machine minus the copper losses can be derived from equation [1] as

$$\frac{3}{2} {i}_{dq}^{T} ( {v}_{dq} - {R}_{s} {i}_{dq} ) = \frac{3}{2} {i}_{dq}^{T} ( \frac{d {λ}_{dq}}{dt} + ω J {λ}_{dq} ) \qquad [ 12 ]$$

which, by the law of energy conservation, is equal to the change in the internal magnetic energy plus the mechanical power output, i.e.,

$$\frac{3}{2} {i}_{d q}^{T} ( \frac{d {λ}_{d q}}{d t} + ω J {λ}_{d q} ) = \frac{3}{2} \frac{d W ( {i}_{d} , {i}_{q} , θ )}{d t} + T ( {i}_{d} , {i}_{q} , θ ) \frac{1}{p} \frac{d θ}{d t} \qquad [ 13 ]$$

where W(i_{d}, i_{q}, θ) is the internal magnetic energy per phase, T(i_{d}, i_{q}, θ) is the instantaneous torque and p is the number of pole pairs of the machine 11. Using equations [2] and [13], the instantaneous torque can be expressed as functions of both stator currents i_{d}, i_{q} and the rotor position θ as:

$$T ( {i}_{d} , {i}_{q} , θ ) = \frac{3 p}{2} {i}_{dq}^{T} ( J {λ}_{dq} + \frac{\partial {λ}_{dq}}{\partial θ} ) - \frac{3 p}{2} \frac{\partial W}{\partial θ} \qquad [ 14 ]$$

The internal magnetic energy can be expressed as the sum of stored potential energy in d and q-axes as

$$W ( {λ}_{d} , {λ}_{q} , θ ) = {\int }_{0}^{{λ}_{d}} {i}_{d} ( τ , 0 , θ ) d τ + {\int }_{0}^{{λ}_{q}} {i}_{q} ( {λ}_{d} , τ , θ ) d τ \qquad [ 15 ]$$

wherein τ is an integration variable.

In equation [15], as the energy is path-independent, for simplicity, the d-axis is magnetized first (0→λ_{d} at λ_{q}=0) and followed by the q-axis (0→λ_{q}). Equivalent procedure can be obtained by computing the magnetic energy following a different path, for example magnetizing the q-axis first (0→λ_{q} at λ_{d}=0) and then the d-axis (0Θλ_{d}).

The potential energy in equation can be reformulated in terms of the state variables: stator currents i_{d}, i_{q} and the rotor position θ. For the d-axis potential energy, the energy to magnetize the d-axis current 0→i_{d} at i_{q}=0 is given by

$${W}_{d} ( {i}_{d} , 0 , θ ) = {i}_{d} {λ}_{d} ( {i}_{d} , 0 , θ ) - {W}_{d}^{′} ( {i}_{d} , 0 , θ ) \qquad [ 16 ]$$

wherein W′_{d}(i_{d}, 0, θ) is the co-energy and is equal to

$${W}_{d}^{′} ( {i}_{d} , 0 , θ ) = {\int }_{0}^{{i}_{d}} {λ}_{d} ( τ , 0 , θ ) d τ \qquad [ 17 ]$$

In regulating a constant i_{d} as the q-axis is magnetized, some potential energy is ejected from the d-axis due to the cross-saturation effect, said potential energy can be represented as (i_{d}λ_{d}(i_{d}, 0, θ)−i_{d}λ_{d}(i_{d}, i_{q}, θ)). Therefore, the net internal magnetic energy is given by

$${W}_{d} ( {i}_{d} , {i}_{q} , θ ) = {i}_{d} {λ}_{d} ( {i}_{d} , {i}_{q} , θ ) - {W}_{d}^{′} ( {i}_{d} , 0 , θ ) \qquad [ 18 ]$$

the partial-derivative of d-axis potential energy, with regard to the rotor position θ, can be expressed as

$$\frac{\partial {W}_{d}}{\partial θ} = {i}_{d} \frac{\partial {λ}_{d}}{\partial θ} ( {i}_{d} , {i}_{q} , θ ) - \frac{\partial {W}_{d}^{′}}{\partial θ} ( {i}_{d} , 0 , θ ) \qquad [ 19 ]$$

Likewise, the potential energy to magnetize q-axis current 0→i_{q} at constant i_{d} can be expressed as

$${W}_{q} ( {i}_{d} , {i}_{q} , θ ) = {i}_{q} {λ}_{q} ( {i}_{d} , {i}_{q} , θ ) - {W}_{q}^{′} ( {i}_{d} , {i}_{q} , θ ) \qquad [ 20 ]$$

wherein

$${W}_{q}^{′} ( {i}_{d} , {i}_{q} , θ )$$

is the co-energy and is equal to

$${W}_{q}^{′} ( {i}_{d} , {i}_{q} , θ ) = {\int }_{0}^{{i}_{q}} {λ}_{q} ( {i}_{d} , τ , θ ) d τ \qquad [ 21 ]$$

the partial-derivative of q-axis potential energy with respect to the rotor position θ can be expressed as

$$\frac{\partial {W}_{q}}{\partial θ} = {i}_{q} \frac{\partial {λ}_{q}}{\partial θ} ( {i}_{d} , {i}_{q} , θ ) - \frac{\partial {W}_{q}^{′}}{\partial θ} ( {i}_{d} , {i}_{q} , θ ) \qquad [ 22 ]$$

From both equation [19] and [22], the derivative of the total internal magnetic energy with regard to the rotor position θ is given by

$$\frac{\partial W}{\partial θ} = {i}_{dq}^{T} \frac{\partial {λ}_{dq}}{\partial θ} - \frac{\partial {W}^{′}}{\partial θ} ( {i}_{d} , {i}_{q} , θ ) \qquad [ 23 ]$$

where a gross co-energy W′(i_{d}, i_{q}, θ) is

$${W}^{′} ( {i}_{d} , {i}_{q} θ ) = {W}_{d}^{′} ( {i}_{d} , 0 , θ ) + {W}_{q}^{′} ( {i}_{d} , {i}_{q} , θ ) \qquad [ 24 ]$$

From [14], [23] and [24], the instantaneous electromagnetic torque accounting for spatial harmonics is given by

$$T ( {i}_{d} , {i}_{q} , θ ) = \frac{3 p}{2} ( {i}_{dq}^{T} J {λ}_{dq} + \frac{\partial {W}^{′}}{\partial θ} ) \qquad [ 25 ]$$

From equation [6] and [14], the derivative of the gross co-energy, with regard to the position in the torque ripple expression [25] can be written as

$$\frac{\partial {W}_{d}^{′}}{\partial θ} = - {\sum }_{h = 6 n} h {\int }_{0}^{{i}_{d}} {L}_{dh} ( τ , 0 ) sin ( h θ - {ϕ}_{dh} ) τ d τ \qquad [ 26 a ]$$

$$\frac{\partial {W}_{q}^{′}}{\partial θ} = - {\sum }_{h = 6 n} h {\int }_{0}^{{i}_{q}} {L}_{qh} ( {i}_{d} , τ ) sin ( h θ - {ϕ}_{qh} ) τ d τ \qquad [ 26 b ]$$

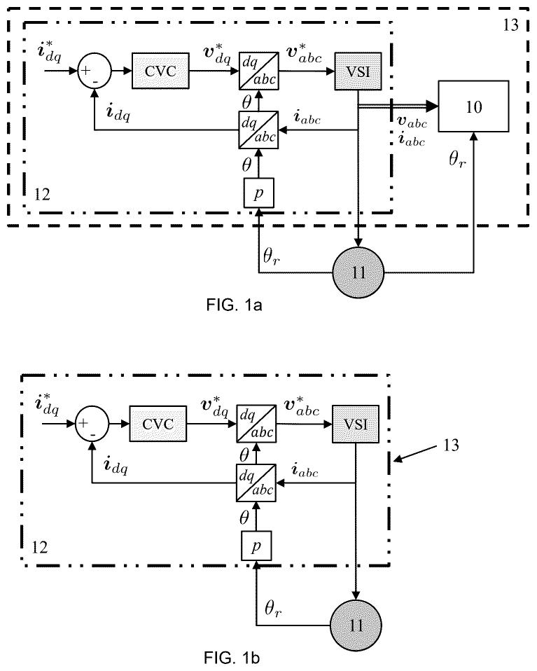

According to the above, the applicant noted that an identification unit 13 configured, inter alia, for identifying the spatial harmonic flux-map can be connected to a synchronous machine 11 as shown in FIGS. 1a-1b. The identification unit 13 is configured to receive the phase voltage vector v_{abc}, the phase current vector i_{abc} and the rotor position er of the synchronous machine 11. Alternatively, e.g. if the star point of the motor is not available, the identification unit 13—in addition to acquiring the phase currents and rotor position θᵣ—can measure the line voltage vector in place of the phase voltage vector.

Preferably, the identification unit 13 can include an inverter 12, with its control board, and a data recorder 10 coupled to the machine 11 and inverter 12 (FIG. 1a). The data recorder is a measurement unit configured to acquire the necessary electrical quantities, said phase voltage vector v_{abc}, a phase current vector i_{abc} and rotor position θᵣ, and it is also preferably provided with computational power in order to carry out the data processing disclosed herein.

Alternatively (FIG. 1b), the identification unit 13 only includes an inverter 12 with its control board, without a data recorder 10 coupled with the machine 11 and inverter 12. In this case, the phase voltage vector—normally not measured by the inverter board—can be replaced by the reference inverter voltage

$${v}_{abc}^{*} .$$

Preferably, the synchronous machine 11 is either a permanent magnets synchronous machine or a synchronous reluctance machine.

It has to be noted that the present description focuses on a synchronous reluctance machine, for exemplary purposes only. The technique disclosed herein can be applied, mutatis mutandis, to a Permanent Magnet Synchronous Motor, PMSM.

For example, as shown in FIG. 1 and considering a synchronous reluctance machine 11 (also indicated as “SyR machine” in the following), said machine 11 is controlled by means of a closed loop current vector control CVC, also known in literature as Field Oriented Control (FOC), implemented with a voltage source inverter VSI. According to above, the three phase currents i_{abc} and three phase voltages v_{abc} at the motor terminal, and the rotor angular position θᵣ are acquired by the data recorder 10, if present.

A closed loop current vector control, implemented with a voltage source inverter VSI is known in the art and is not described in detail in the following.

According to the present invention, the identification unit 13 is configured to identify the spatial harmonic flux-map of the machine 11. In particular, the identification unit 13 is configured for performing the following operations, while the machine 11 is driven at a constant speed:
scanning a dq current plane of said motor with two proportional-integral current controllers;
acquiring phase current i_{abc}, line voltage v_{abc} and rotor position θ during said scanning;
calculating the stator flux-linkage λ_{αβ} in a stationary reference frame from a voltage equation from at least one electrical cycle data as

$${λ}_{α β} = \int ( {v}_{α β} - {R}_{s} {i}_{α β} ) dt$$

wherein
λ_{αβ} is the stator flux-linkage vector in a stationary reference frame;
v_{αβ} is a stator voltage vector in a stationary reference frame;
Rₛ is a stator resistance and
i_{αβ} is a stator current vector in a stationary reference frame;
extracting harmonics in the measured phase current

$${i}_{d}^{*} , {i}_{q}^{*}$$

by means of a Fourier transform;
extracting harmonics in the estimated stator flux

$${λ}_{d}^{*} , {λ}_{q}^{*}$$

in a synchronous reference frame by means of a Fourier transform;
   wherein the sine and cosine components of d-axis harmonic flux and/or q-axis harmonic flux is/are represented as the resulting interaction between the harmonic currents and the harmonic inductance and the expressions Λ_{d}=I_{d}L_{d}+λₘ; Λ_{q}=I_{q}L_{q} hold
   wherein Λ_{d}; Λ_{q} are columns vector flux matrix, I_{d}; I_{q} are a square matrix, L_{d}; L_{q} are inductance column vector matrix.

Preferably, an external driving machine (not shown in figures) is mechanically connected to the machine 11 and configured to drive the machine 11 at a constant speed. In other words, a dq current plane of the machine 11 under test is explored while being driven at a constant speed by an external driving machine (not shown in FIG. 1). For example, said constant speed is set to 0.1-0.5 p.u., preferably, as a trade-off between back-emf reliability and iron losses minimization said constant speed is set to 0.33 p.u.

In particular, the scanning of the dq current plane of the machine 11 comprises:
setting the q-axis current i_{q}, from a minimum value to a maxim value, at predetermined values; each value being maintained for a respective time interval t(i);
increasing a d-axis current i_{d} from a minimum value to a maximum value in each of said time intervals t(i).

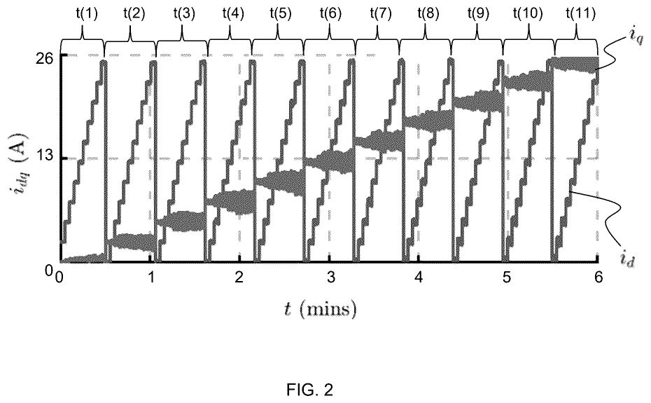

An example of current trajectories i_{dq}, acquired at a constant speed are shown in FIG. 2, wherein eleven successive time intervals t(i) are shown.

Preferably, said harmonics in the measured phase current

$${i}_{d}^{*} , {i}_{q}^{*}$$

are expressed as:

$${i}_{d} ( {i}_{d}^{*} , {i}_{q}^{*} , θ ) = {i}_{d0} ( {i}_{d}^{*} , {i}_{q}^{*} ) + {\sum }_{h = 6 n} {i}_{dh} ( {i}_{d}^{*} , {i}_{q}^{*} ) cos ( h θ - {ϕ}_{dh}^{i} ) \\ {i}_{q} ( {i}_{d}^{*} , {i}_{q}^{*} , θ ) = {i}_{q 0} ( {i}_{d}^{*} , {i}_{q}^{*} ) + {\sum }_{h = 6 n} {i}_{qh} ( {i}_{d}^{*} , {i}_{q}^{*} ) cos ( h θ - {ϕ}_{qh}^{i} )$$

wherein

$${i}_{d 0} ≅ {i}_{d}^{*} and {i}_{q 0} ≅ {i}_{q}^{*}$$

are the average currents, i_{dh} and i_{qh} are the current harmonic components magnitude and

$${ϕ}_{dh}^{i} and {ϕ}_{qh}^{i}$$

are the current harmonic components phase angle.
Preferably, the computed stator flux vector in a stationary reference frame λ_{αβ} is rotated by the angle θ, thus obtaining the stator flux vector in a rotating reference frame λ_{dq}

Preferably, said harmonics in the estimated stator flux λ*_{d}, λ*_{q} in a synchronous reference frame are expressed as:

$${λ}_{d} ( {i}_{d}^{*} , {i}_{q}^{*} , θ ) = {λ}_{d 0} ( {i}_{d}^{*} , {i}_{q}^{*} ) + {\sum }_{h = 6 n} {λ}_{dh} ( {i}_{d}^{*} , {i}_{q}^{*} ) cos ( h θ - {ϕ}_{dh}^{λ} )$$

$${λ}_{q} ( {i}_{d}^{*} , {i}_{q}^{*} , θ ) = {λ}_{q 0} ( {i}_{d}^{*} , {i}_{q}^{*} ) + {\sum }_{h = 6 n} {λ}_{qh} ( {i}_{d}^{*} , {i}_{q}^{*} ) cos ( h θ - {ϕ}_{dh}^{λ} )$$

wherein λ_{d0} and λ_{q0} are the average fluxes; λ_{dh} and λ_{qh} are the flux harmonic components magnitude;

$${ϕ}_{dh}^{λ} and {ϕ}_{q h}^{λ}$$

are the flux harmonic components phase angle.

Preferably the identification unit 13 is further configured for:
calculating an instantaneous electromagnetic torque T(i_{d}, i_{q}, θ) as

$$T ( {i}_{d} , {i}_{q} , θ ) = \frac{3 p}{2} ( {i}_{d q}^{T} J {λ}_{dq} + \frac{\partial {W}^{′}}{\partial θ} )$$

wherein the d-axis and q-axis components of the derivative of the gross co-energy are:

$$\frac{\partial {W}_{d}^{′}}{\partial θ} = - {\sum }_{h = 6 n} h {\int }_{0}^{{i}_{d}} {L}_{dh} ( τ , 0 ) sin ( h θ - {ϕ}_{dh} ) τ d τ$$

$$\frac{\partial {W}_{q}^{′}}{\partial θ} = - {\sum }_{h = 6 n} h {\int }_{0}^{{i}_{q}} {L}_{qh} ( {i}_{d} , τ ) sin ( h θ - {ϕ}_{qh} ) τ d τ$$

wherein L_{d0} and L_{q0} are the fundamental inductances, L_{dh} and L_{dh} are the inductances harmonic components magnitude; φ_{dh} and φ_{qh} are the inductances harmonic components phase angle.

The proposed commissioning technique is validated experimentally on a 4.4 KW SyR motor on a dSPACE DS1103 control platform running at a sampling frequency of 10 KHz. The raw data for identification is acquired using HBM GEN3i data recorders at a sampling frequency of 2 MHz.

More details on the SyR machine used for the validation can be found in S. Ferrari and G. Pellegrino, “FEAfix: FEA Refinement of Design Equations for Synchronous Reluctance Machines” IEEE Transactions on Industry Applications, vol. 56, no. 1, pp. 256-266, 2020.

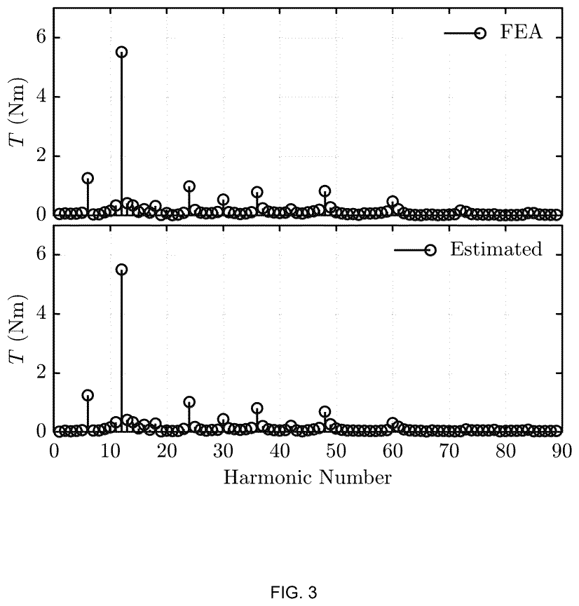

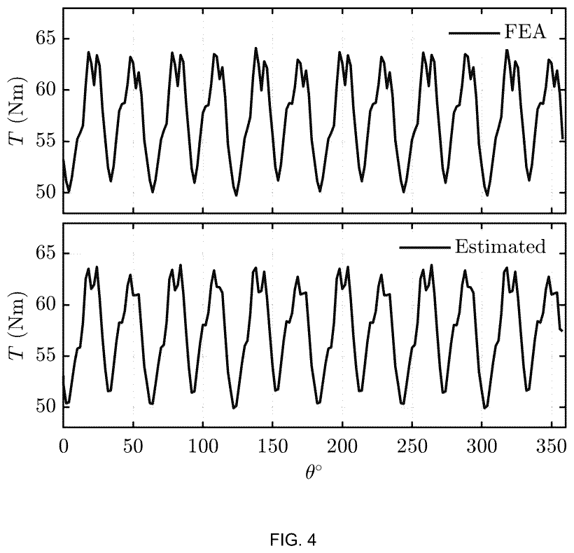

The torque-map is evaluated both on the identified flux-map data by means of the method according to the present invention and a reference one calculated through Finite Element Analysis (FEA). As shown in FIGS. 3 and 4, a good correlation is observed with an accurate estimation of the dominant 12th harmonic.

1. A method for identifying the spatial harmonic flux-map of an electrical machine, the method comprising:
driving said electrical machine at a constant speed by an external driver;
scanning a dq current plane of said electrical machine by a proportional-integral current controller;
acquiring phase current, line voltage and rotor position of said electrical machine during said scanning;
calculating a stator flux-linkage, in a stationary reference frame αβ, from a voltage equation from at least one electrical cycle data as
$${λ}_{αβ} = \int ( {v}_{αβ} - {R}_{s} {i}_{αβ} ) dt$$
wherein
λ_{αβ} is the stator flux-linkage vector in a stationary reference frame;
v_{αβ} is the stator voltage vector in a stationary reference frame;
Rₛ is the stator resistance and
i_{αβ} is the stator current vector in a stationary reference frame;
extracting harmonics in the measured phase current by a Fourier transform;
extracting harmonics in the estimated stator flux in a synchronous reference frame by a Fourier transform;
wherein the expressions Λ_{d}=I_{d}L_{d}+Λₘ; Λ_{q}=I_{q}L_{q} hold
wherein
Λ_{d}; Λ_{q}; λₘ are columns vector flux matrix,
I_{d}; I_{q} are a square matrix,
L_{d}; L_{q} are inductance columns vector matrix.

2. The method according to claim 1, wherein said electrical machine is either a permanent magnets synchronous machine or a synchronous reluctance machine.

3. The method according to claim 1, wherein said constant speed is comprised between 0.2 and 0.5 p.u., preferably equal to 0.33 p.u.

4. The method according to claim 1, wherein said scanning a dq current plane of said electrical machine with a proportional-integral current controller comprises:
setting a q-axis current (i_{q}), from a minimum value to a maxim value, at predetermined values; each value being maintained for a respective time interval (t(i));
increasing a d-axis current (i_{d}) from a minimum value to a maximum value in each of said time intervals (t(i)).

5. The method according to claim 1, wherein said harmonics in the measured phase current
$${i}_{d}^{*} , {i}_{q}^{*}$$
are expressed as:
$${i}_{d} ( {i}_{d}^{*} , {i}_{q}^{*} , θ ) = {i}_{d 0} ( {i}_{d}^{*} , {i}_{q}^{*} ) + {\sum }_{h = 6 n} {i}_{d h} ( {i}_{d}^{*} , {i}_{q}^{*} ) cos ( h θ - {ϕ}_{d h}^{i} )$$
$${i}_{q} ( {i}_{d}^{*} , {i}_{q}^{*} , θ ) = {i}_{q 0} ( {i}_{d}^{*} , {i}_{q}^{*} ) + {\sum }_{h = 6 n} {i}_{qh} ( {i}_{d}^{*} , {i}_{q}^{*} ) cos ( h θ - {ϕ}_{qh}^{i} )$$
wherein
$${i}_{d 0} = {i}_{d}^{*} and {i}_{q 0} = {i}_{q}^{*}$$
are the average currents, i_{dh} and i_{qh} are the current harmonic components magnitude and
$${ϕ}_{d h}^{i} and {ϕ}_{q h}^{i}$$
are the current harmonics components phase angle.

6. The method according to claim 1, wherein said harmonics in the estimated stator flux
$${λ}_{d}^{*} , {λ}_{q}^{*}$$
in a synchronous reference frame are expressed as:
$${λ}_{d} ( {i}_{d}^{*} , {i}_{q}^{*} , θ ) = {λ}_{d 0} ( {i}_{d}^{*} , {i}_{q}^{*} ) + {\sum }_{h = 6 n} {λ}_{d h} ( {i}_{d}^{*} , {i}_{q}^{*} ) cos ( h θ - {ϕ}_{d h}^{λ} )$$
$${λ}_{q} ( {i}_{d}^{*} , {i}_{q}^{*} , θ ) = {λ}_{q 0} ( {i}_{d}^{*} , {i}_{q}^{*} ) + {\sum }_{h = 6 n} {λ}_{qh} ( {i}_{d}^{*} , {i}_{q}^{*} ) cos ( h θ - {ϕ}_{qh}^{λ} )$$
wherein Λ_{d0} and λ_{q0} are the average fluxes; Λ_{dh} and λ_{qh} are the harmonic flux components magnitude;
$${ϕ}_{d h}^{λ} and {ϕ}_{q h}^{λ}$$
are the harmonic flux components phase angle.

7. A method for torque ripple map evaluation without torque transducer, comprising:
a. Performing the method of claim 1;
b. Performing a torque ripple map evaluation based on the spatial harmonic flux-map of said electrical machine.

8. The method according to claim 7, wherein said torque ripple map evaluation comprises:
calculating an instantaneous electromagnetic torque as
$$T ( {i}_{d} , {i}_{q} , θ ) = \frac{3 p}{2} ( {i}_{d q}^{T} I {λ}_{d q} + \frac{\partial {W}^{′}}{\partial θ} )$$
wherein
i_{dq} is the stator current vector in a synchronous reference frame;
p is the number of pole pairs of the machine;
λ_{dq} is stator flux-linkage vector in a synchronous reference frame;
and the d-axis and q-axis components of the derivative of the gross co-energy
$$\frac{\partial {W}^{′}}{\partial θ}$$
are:
$$\frac{\partial {W}_{d}^{′}}{\partial θ} = - {\sum }_{h = 6 n} h {\int }_{0}^{{i}_{d}} {L}_{d h} ( τ , 0 ) sin ( h θ - {ϕ}_{d h} ) τ d τ$$
$$\frac{\partial {W}_{q}^{′}}{\partial θ} = - {\sum }_{h = 6 n} h {\int }_{0}^{{i}_{q}} {L}_{q h} ( {i}_{d} , τ ) sin ( h θ - {ϕ}_{q h} ) τ d τ$$
L_{d0} and L_{q0} are the fundamental inductances, L_{dh} and L_{qh} are the harmonic components magnitude; φ_{dh} and φ_{qh} are the harmonic components phase angle.

9. The method according to claim 7, wherein torque measurement is not performed.
